(19) United States
(12) Patent Application Publication
(10) Pub. No.: US 2019/0204505 A1
(43) Pub. Date: Jul. 4, 2019

(54) ADDITIVE PHOTONIC INTERCONNECTS IN MICROELECTRONIC DEVICE

(71) Applicant: Texas Instruments Incorporated, Dallas, TX (US)

(72) Inventors: Benjamin Stassen Cook, Addison, TX (US); Daniel Lee Revier, Dallas, TX (US)

(73) Assignee: Texas Instruments Incorporated, Dallas, TX (US)

(21) Appl. No.: 15/859,494

(22) Filed: Dec. 30, 2017

(51) Int. Cl. G02B 6/12; H01L 31/12; H01L 31/0203; H01L 31/02; G02B 6/138; H05K 1/02; H01P 3/16

(52) U.S. Cl. CPC G02B 6/12004; H01L 31/12; H01L 31/0203; G02B 2006/12147; G02B 6/138; H05K 1/024; H01P 3/16; H01L 31/02005

(57) ABSTRACT

A microelectronic device includes a photonic die having a die input/output (I/O) port. The microelectronic device includes a photonic connection between the first photonic I/O port and the second photonic I/O port. The photonic connection has a dielectric signal pathway for a photonic signal from the first photonic I/O port to the second photonic I/O port. The second photonic I/O port may be a package photonic I/O port at an exterior of the microelectronic device, or may be another die photonic I/O port on another photonic die of the microelectronic device. The photonic connection is formed using at least one additive process, such as by selectively placing material for the photonic connection in a region for the photonic connection.

### TECHNICAL FIELD

This relates generally to microelectronic devices, and more particularly to photonic connections in microelectronic devices.

### BACKGROUND

A microelectronic device may have a photonic die, which may include photonic components, such as optical signal sources and detectors, infrared signal sources and detectors, terahertz signal sources and detectors, or microwave (e.g. D-band) sources and detectors. The photonic die may have photonic input/output ports to communicate the optical signals, infrared signals, terahertz signals, or millimeter wave signals with devices external to the microelectronic device. The optical signals and infrared signals may be transmitted through optical fiber connections. The terahertz signals may be transmitted through optical fiber channels or waveguides. The millimeter wave signals may be transmitted through waveguides. The photonic connections, such as the optical fiber channels and waveguides from the photonic ports on the photonic die to photonic ports of the microelectronic device, may be expensive to produce and assemble, compared to wire bonds or bump bonds used for conventional electrical signals.

### SUMMARY

A microelectronic device includes a photonic die configured to communicate a photonic signal through a first photonic input/output (I/O) port of the photonic die. The microelectronic device includes a photonic connection between the first photonic I/O port and a second photonic I/O port. The photonic connection has a dielectric signal pathway for the photonic signal from the first photonic I/O port to the second photonic I/O port. The photonic connection is formed using at least one additive process. The second photonic I/O port may be a package photonic I/O port proximate to an exterior boundary of the microelectronic device. The second photonic I/O port may be a die photonic I/O port on the photonic die or on a second photonic die in the microelectronic device.

### BRIEF DESCRIPTION OF THE DRAWINGS

FIG. 1A and FIG. 1B are cross sections of an example microelectronic device having at least one photonic connection.

FIG. 2A and FIG. 2B are cross sections of another example microelectronic device having at least one photonic connection.

FIG. 3A through FIG. 3F are cross sections of a microelectronic device having at least one photonic connection, depicted in stages of an example method of formation.

FIG. 4A through FIG. 4D are cross sections of a microelectronic device having at least one photonic connection, depicted in stages of another example method of formation.

FIG. 5 is a cross section of a further example microelectronic device having at least one photonic connection.

FIG. 6 is a cross section of another example microelectronic device having at least one photonic connection.

### DETAILED DESCRIPTION OF EXAMPLE EMBODIMENTS

The drawings are not necessarily drawn to scale. Example embodiments are not limited by the illustrated ordering of acts or events, as some acts or events may occur in different orders and/or concurrently with other acts or events. Furthermore, not all illustrated acts or events are required to implement a methodology in accordance with example embodiments.

A microelectronic device includes a photonic die having a first photonic I/O port configured to communicate a photonic signal, such as to transmit or receive the photonic signal, through the first photonic I/O port. The photonic signal may include a signal in the optical band, so the photonic signal may include components having wavelengths between 100 nanometers and 2 microns. The photonic signal may include a signal in the infrared band, so the photonic signal may include components having wavelengths between 2 microns and 100 microns. The photonic signal may include a signal in the terahertz band, so, the photonic signal may include components having wavelengths between 100 microns and 1 millimeter. The photonic signal may include a signal in the millimeter wave band, so, the photonic signal may include components having wavelengths between 1 millimeter and 10 millimeters. The microelectronic device includes a second photonic I/O port for the photonic signal. In one aspect, the second photonic I/O port may be a package photonic I/O port, which is part of a structural package of the microelectronic device, separate from the photonic die. In another aspect, the second photonic I/O port may be a die photonic I/O port on the photonic die. In a further aspect, the second photonic I/O port may be a die photonic I/O port on a second photonic die of the microelectronic device.

The microelectronic device further includes a photonic connection between the first photonic I/O port and the second photonic I/O port for the photonic signal. The photonic connection has a dielectric signal pathway for the photonic signal, extending from the first photonic I/O port to the second photonic I/O port. The dielectric signal pathway may include a solid dielectric material, such as a solid material having a refractive index greater than air, such as an organic polymer, a silicone organic polymer, an inorganic dielectric material, or such.

The photonic connection is formed using at least one additive process. In this description, the term “additive process” can mean a process of forming a component by selectively placing material for the component in a region for the component. Examples of additive processes include binder jetting, material jetting, directed energy deposition, material extrusion, material jetting, powder bed fusion, sheet lamination, vat photopolymerization, direct laser deposition, electrostatic deposition, laser sintering, electrochemical deposition, and photo-polymerization extrusion.

Use of the at least one additive process to form the photonic connection does not preclude use of a subtractive process to form a portion of the photonic connection. Subtractive processes include mechanical removal of material, such as by machining or laser ablation. Forming the photonic connection may include forming sacrificial material, used as temporary scaffolding for the at least one additive process; the sacrificial material is removed later, such as by dissolution or evaporation.

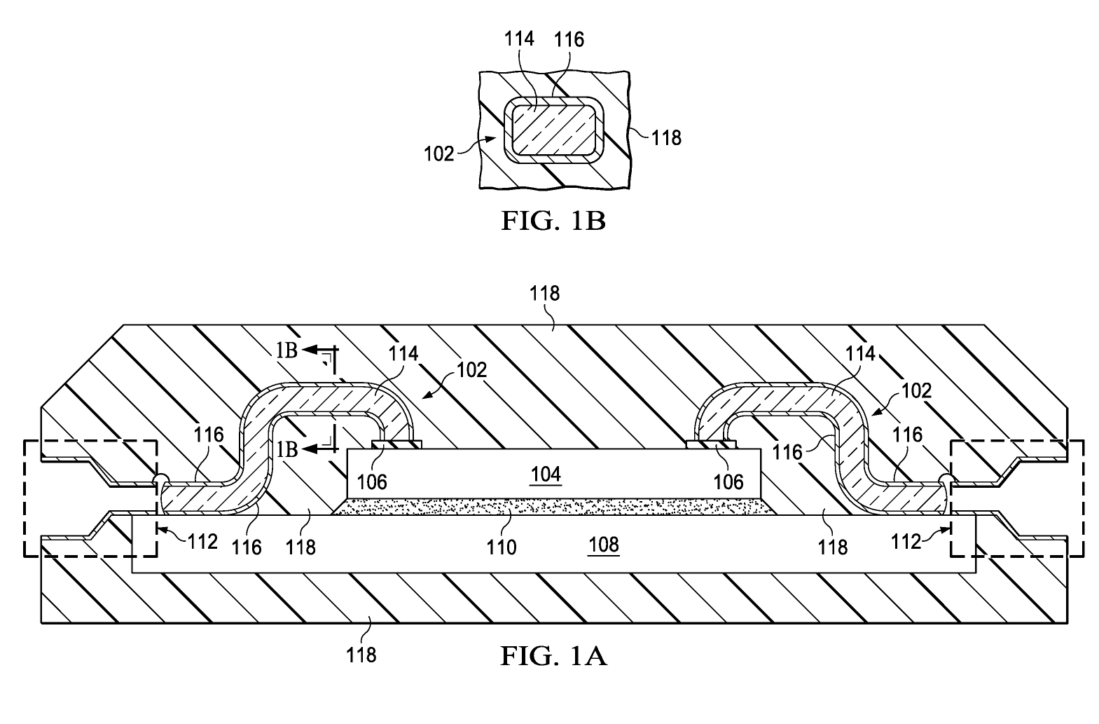

FIG. 1A and FIG. 1B are cross sections of an example microelectronic device 100 having at least one photonic connection 102. Referring to FIG. 1A, the microelectronic device 100 includes a photonic die 104 configured for processing photonic signals. The photonic die 104 includes one or more first photonic I/O ports 106 for transmitting or receiving the photonic signals. The first photonic I/O ports 106 may be structured to transmit or receive components of the photonic signals in the optical band, the infrared band, the terahertz band, or the millimeter wave band.

The microelectronic device 100 may optionally include a package substrate 108, such as a ceramic lead frame, a metal lead frame, a printed circuit board, or the like. The photonic die 104 may be coupled to the package substrate 108, if present, by a die attach material 110, such as an adhesive, a solder, a heatsink material, or the like.

The microelectronic device 100 further includes one or more second photonic I/O ports 112 for the photonic signals. In this example, the second photonic I/O ports 112 are a part of a structural package of the microelectronic device 100, and are separate from the photonic die 104. For example, each first photonic I/O port 106 may be communicatively coupled to a respective second photonic I/O port 112. In this example, the second photonic I/O ports 112 may include receptacles for external waveguides, as depicted in FIG. 1A. Other structures for the second photonic I/O ports 112 are within the scope of this example.

The microelectronic device 100 includes at least one photonic connection 102 extending from one of the first photonic I/O ports 106 to one of the second photonic I/O ports 112. Each photonic connection 102 has a dielectric signal pathway 114 for the corresponding photonic signal. In one version of this example, the dielectric signal pathway 114 may include organic polymeric dielectric material, such as epoxy, polyurethane, polyester, or the like. In another version, the dielectric signal pathway 114 may include a silicone organic polymeric dielectric material. In a further version, the dielectric signal pathway 114 may include an inorganic dielectric material, such as silicate-based material, aluminum oxide, boron nitride, or the like, wherein the inorganic dielectric material may have a uniform, amorphous composition, or may include nanoparticles of the inorganic dielectric material. The dielectric signal pathway 114 may optionally include an organic or inorganic binder material with the nanoparticles of the inorganic dielectric material. In yet another version, the dielectric signal pathway 114 may include gaseous dielectric material, such as air, nitrogen, argon, sulfur dioxide, or the like.

In this example, each of the photonic connections 102 may include an electrically conductive envelope 116 surrounding the corresponding dielectric signal pathway 114. The electrically conductive envelope 116 may include electrically conductive nanoparticles of materials, such as carbon nanotubes, silver, nickel, copper coated with nickel, graphene, gold, or the like. The electrically conductive envelope 116 may include binder material, such as organic polymer with the electrically conductive nanoparticles. FIG. 1B is a cross section of one of the photonic connections 102, showing the electrically conductive envelope 116 surrounding the dielectric signal pathway 114. The photonic connections 102 may have square, rectangular, round, oval, rounded rectangular, or other cross sectional shapes.

Referring again to FIG. 1A, the microelectronic device 100 may include other structural elements, such as an encapsulation material 118 around the photonic die 104, the package substrate 108, and the photonic connections 102. In this example, the encapsulation material 118 may surround and contact the photonic connections 102, which may advantageously provide mechanical support for the photonic connections 102. Other elements in the microelectronic device 100, such as a semiconductor die, passive components, electrical leads and the like, are within the scope of this example. The photonic die 104 may include conventional bond pads for power, ground, and electrical signals, such as clock signals, input data, and output data. These conventional bond pads may be electrically coupled to leads of the microelectronic device 100, such as by wire bonds or bump bonds.

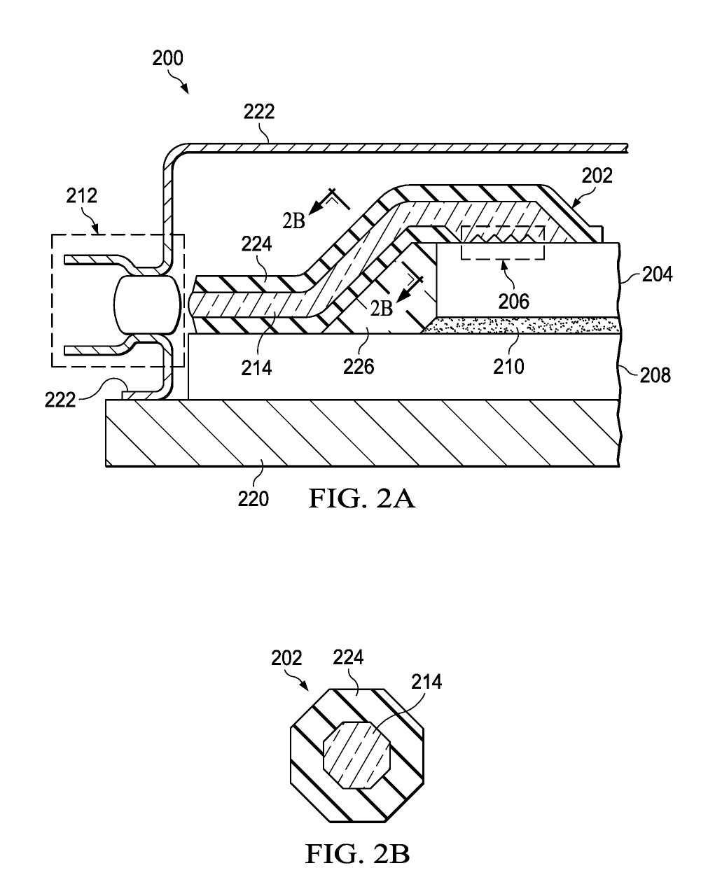

FIG. 2A and FIG. 2B are cross sections of another example microelectronic device 200 having at least one photonic connection 202. The microelectronic device 200 includes a photonic die 204 with at least one first photonic I/O port 206 for photonic signals. The first photonic I/O port 206 may be structured to transmit or receive components of the photonic signals in the optical band, the infrared band, the terahertz band, or the millimeter wave band. In this example, the first photonic I/O port 206 may include surface gratings, as depicted in FIG. 2A, to couple the photonic signals into and out of the photonic die 204.

The microelectronic device 200 may optionally include a package substrate 208, such as a ceramic lead frame, a metal lead frame, a printed circuit board, or the like. The photonic die 204 may be coupled to the package substrate 208, if present, by a die attach material 210, such as adhesive, solder, heatsink material, or the like.

The microelectronic device 200 further includes at least one second photonic I/O port 212 for the photonic signals. Each first photonic I/O port 206 may be communicatively coupled to a respective second photonic I/O port 212. In this example, the second photonic I/O port 212 may include a lens for focusing external photonic connections, as depicted in FIG. 2A. Other structures for the second photonic I/O port 212 are within the scope of this example.

The microelectronic device 200 may include other structural elements, such as a package base 220 and a package lid 222. The package base 220 may include metal, ceramic, glass, or other structural material. The package lid 222 may include metal formed by stamping, plastic formed by molding, or other packaging material. Other elements in the microelectronic device 200 are within the scope of this example. The photonic die 204 may include conventional bond pads, electrically connected to leads of the microelectronic device 200.

The microelectronic device 200 has a photonic connection 202 extending from the first photonic I/O port 206 to the second photonic I/O port 212. The photonic connection 202 has a dielectric signal pathway 214 for the corresponding photonic signal. In one version of this example, the dielectric signal pathway 214 may include organic or silicon organic polymeric dielectric material. In another version, the dielectric signal pathway 214 may include inorganic dielectric material. The dielectric signal pathway 214 may optionally include a binder material with the inorganic dielectric material. The dielectric signal pathway 214 may have an index of refraction greater than 2.0 to provide for internal reflection of the photonic signal as it travels through the dielectric signal pathway 214.

In this example, the photonic connection 202 may include a dielectric cladding 224 surrounding the corresponding dielectric signal pathway 214. The dielectric cladding 224 may include dielectric material with an index of refraction lower than the index of refraction of the dielectric signal pathway 214, to maintain internal reflection of the photonic signal as it travels through the dielectric signal pathway 214. The dielectric cladding 224 may include organic or silicone organic polymer material, or may include inorganic dielectric material. The dielectric cladding 224 may provide isolation for the dielectric signal pathway 214, such as at points of contact with the package substrate 208. In one version of this example, the photonic connection 202 may have a polygonal cross sectional shape, as depicted in FIG. 2B. In another version, the photonic connection 202 may have a round or oval cross sectional shape. In a further version, the photonic connection 202 may have a rounded rectangular or rounded square cross sectional shape. Other cross sectional shapes for the photonic connection 202 are within the scope of this example.

Referring again to FIG. 2A, in this example, the photonic connection 202 may be located on a support structure 226. For example, the support structure 226 may extend from the photonic die 204 to the package substrate 208. The support structure 226 may provide structural support for the photonic connection 202 during formation of the photonic connection 202 or during subsequent assembly of the microelectronic device 200. The support structure 226 may include polymeric material, or nanoparticles in a binder material, ceramic material, metal, or other structural material.

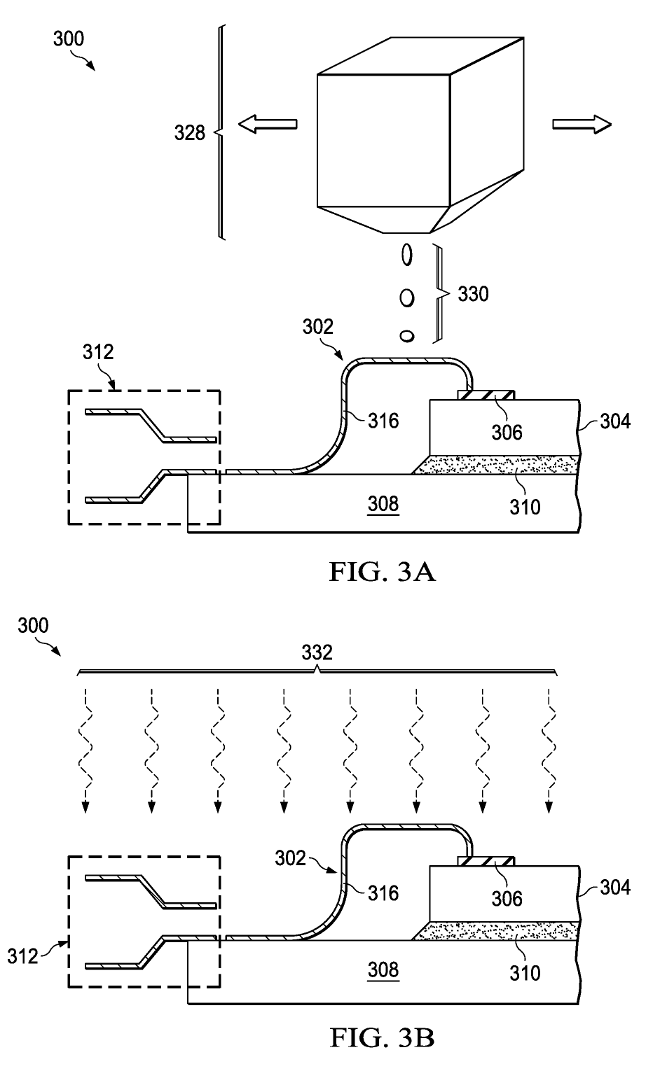

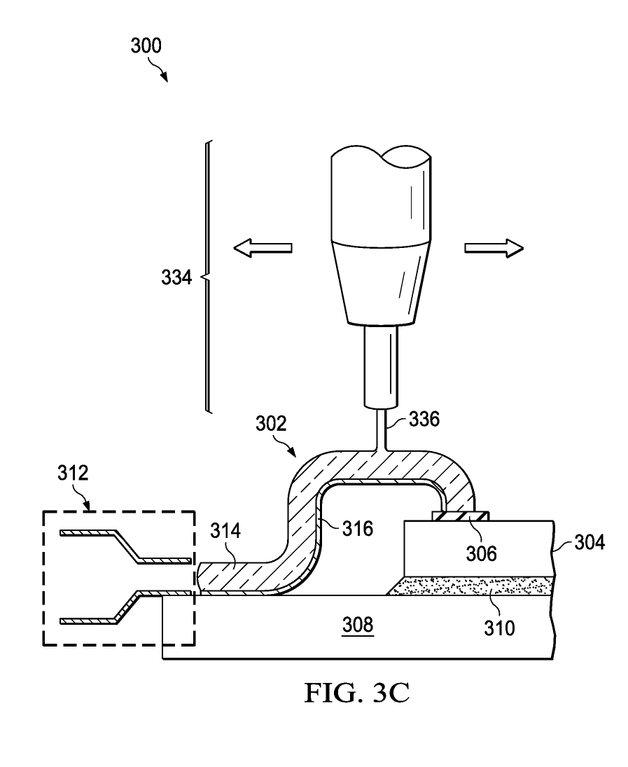

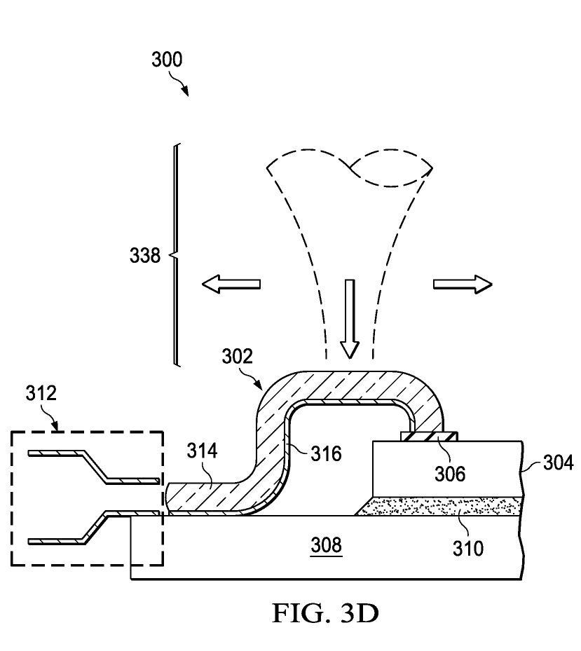

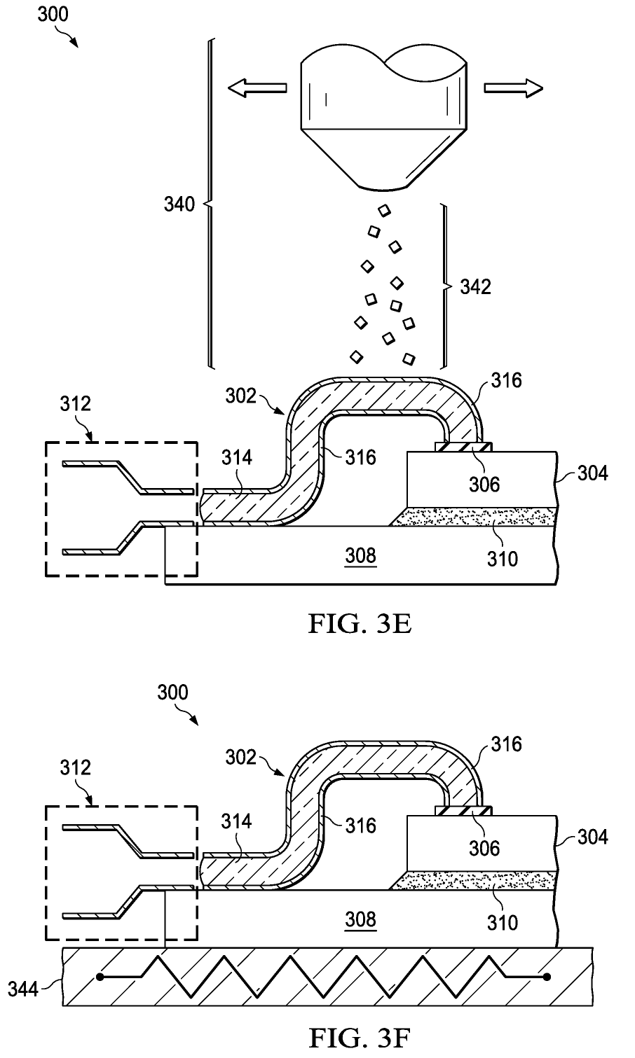

FIG. 3A through FIG. 3F are cross sections of a microelectronic device 300 having at least one photonic connection 302, depicted in stages of an example method of formation. In this example, the microelectronic device 300 includes a photonic die 304, which may be attached to a package substrate 308 before forming the photonic connection 302. The photonic die 304 includes at least one first photonic I/O port 306 configured to transmit or receive photonic signals. The photonic die 304 may be attached to the package substrate 308 by a die attach material 310, such as adhesive, solder, heatsink material, or the like. The microelectronic device 300 of this example also includes a second photonic I/O port 312, which is attached to the package substrate 308 before forming the photonic connection 302.

The photonic connection 302 of this example is formed to extend from the first photonic I/O port 306 to the second photonic I/O port 312. The photonic connection 302 is formed by at least one additive process. In this example, the photonic connection 302 is formed by a series of additive processes, including a first additive process 328, which is depicted in FIG. 3A as a material jetting process, such as an inkjet process or the like. Other additive processes, such as binder jetting, material jetting, directed energy deposition, material extrusion, powder bed fusion, sheet lamination, vat photopolymerization, direct laser deposition, electrostatic deposition, laser sintering, electrochemical deposition, and photo-polymerization extrusion, are within the scope of this example. In this example, the first additive process 328 forms a first portion of an electrically conductive envelope 316 of the photonic connection 302. The first additive process 328 dispenses a first additive material 330, which includes electrically conductive material, such as metal nanoparticles, graphene flakes, or such. The first additive material 330 may include binder material, and may include solvents. The first additive material 330 may be dispensed onto a temporary or permanent structure, not shown, to provide a desired shape and form factor for the photonic connection 302.

Referring to FIG. 3B, the partially-formed photonic connection 302 may be heated to remove at least a portion of volatile material in the first additive material 330 of FIG. 3A that was dispensed to form the first portion of the electrically conductive envelope 316. For example, the volatile material removed from the first additive material 330 may include solvents in the first additive material 330. The partially-formed photonic connection 302 may be heated by a blanket radiant heat process 332 as depicted schematically in FIG. 3B. Other heating processes, such as a chain furnace process, a hot plate process, a scanned radiant process, or a forced convention process, are within the scope of this example. Heating the partially-formed photonic connection 302 may also induce a chemical or physical reaction in the first additive material 330, such as polymerization of binder material or sintering of metal nanoparticles.

Referring to FIG. 3C, a second additive process 334 forms a dielectric signal pathway 314 of the photonic connection 302. The second additive process 334 may include a material jetting process, as depicted in FIG. 3C. The second additive process 334 may dispense a second additive material 336, such as a polymer, a ceramic slurry, or an ink including dielectric nanoparticles in a binder material. The second additive material 336 may include volatile material, such as solvent. The second additive process 334 may dispense the second additive material 336 in a softened state at a temperature above room temperature. Other implementations of the second additive process 334, such as binder jetting, directed energy deposition, material extrusion, material jetting, powder bed fusion, sheet lamination, direct laser deposition, electrostatic deposition, laser sintering, and electrochemical deposition, are within the scope of this example. Formation of the dielectric signal pathway 314 by the second additive process 334 may involve a sacrificial material, not shown, to provide a desired shape and form factor for the photonic connection 302.

Referring to FIG. 3D, the partially-formed photonic connection 302 may be heated to remove volatile material from the dielectric signal pathway 314, or to induce a chemical or physical reaction in the dielectric signal pathway 314. An example of the volatile material, which may be removed from the dielectric signal pathway 314 may include solvents in the second additive material 336 of FIG. 3C. An example of the chemical reaction, which may be induced may include polymerization of binder material in the second additive material 336. An example of the physical reaction, which may be induced may include adhesion of the dielectric nanoparticles to each other by formation of inorganic covalent bonds in the second additive material 336. The partially-formed photonic connection 302 may be heated by a scanned radiant process 338, as depicted in FIG. 3D. Alternatively, the partially-formed photonic connection 302 may be heated by a blanket radiant heating process, a chain furnace process, a hot plate process, a forced convention process, or such.

Referring to FIG. 3E, a second portion of the electrically conductive envelope 316 of the photonic connection 302 is formed by a third additive process 340. The third additive process 340 may include an electrostatic deposition process, as depicted in FIG. 3E. In other versions of this example, the third additive process 340 may include binder jetting, material jetting, directed energy deposition, material extrusion, material jetting, powder bed fusion, sheet lamination, direct laser deposition, laser sintering, and electrochemical deposition. The third additive process 340 may dispense a third additive material 342, such as electrically conductive nanoparticles as depicted in FIG. 3E, onto the photonic connection 302. The third additive material 342 may include binder material or solvent with the conductive nanoparticles.

Referring to FIG. 3F, the photonic connection 302 may be heated to remove volatile material from the components of the photonic connection 302, such as the dielectric signal pathway 314 and the electrically conductive envelope 316, or to induce a chemical or physical reaction in the components of the photonic connection 302. The photonic connection 302 may be heated by a hot plate process 344, as depicted in FIG. 3F. Alternatively, the partially-formed photonic connection 302 may be heated by a blanket radiant heating process, a chain furnace process, a scanned radiant process, a forced convention process, or such.

Forming the photonic connection 302 using additive processes may advantageously reduce cost and complexity of the microelectronic device 300 while improving performance and reliability of the microelectronic device 300, compared to assembling the microelectronic device 300 using prefabricated photonic connections. Other instances of photonic connections to the photonic die 304 may be formed in parallel with the photonic connection 302. After the photonic connection 302 is formed, formation of the microelectronic device 300 may proceed with formation of other connections to the photonic die 304, such as wire bonds. Subsequently, formation of the microelectronic device 300 may proceed by forming additional package elements, such as encapsulation material and the like. Any of the package elements, including the package substrate 308, the encapsulation material, or the other connections (non-photonic) to the photonic die 304, may also be formed by one or more additive processes.

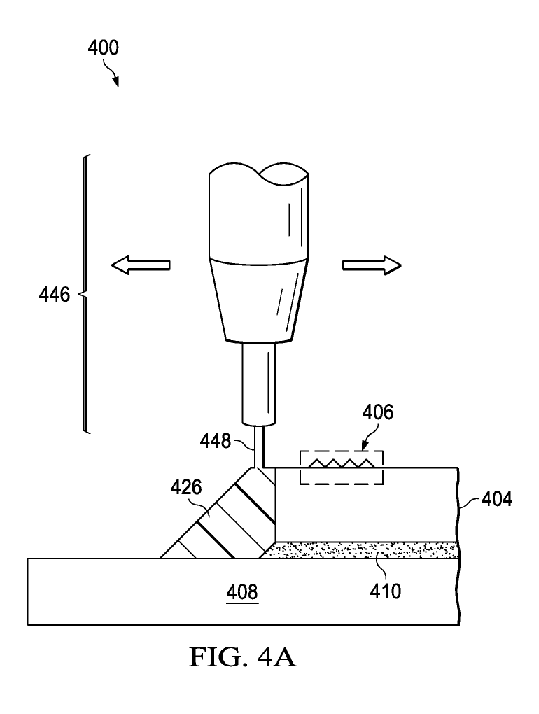

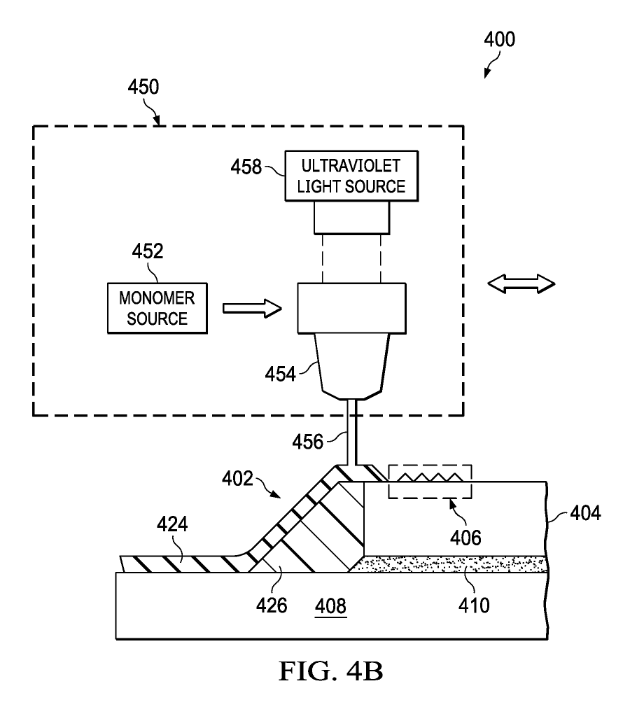

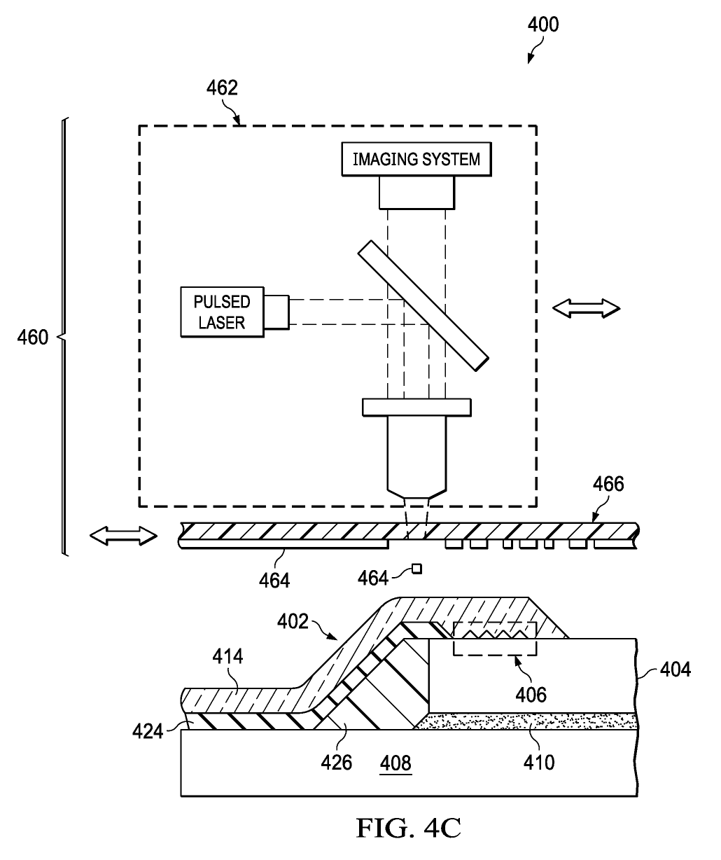

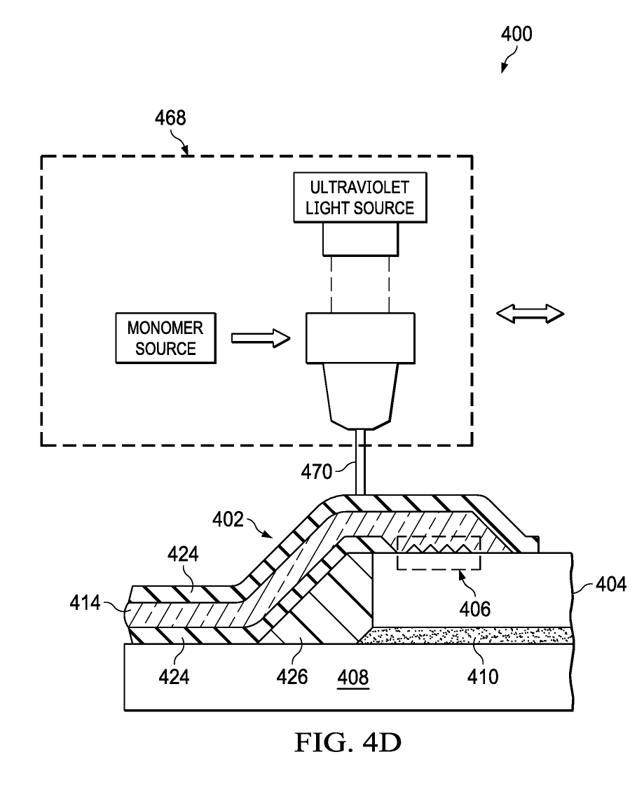

FIG. 4A through FIG. 4D are cross sections of a microelectronic device 400 having at least one photonic connection 402, depicted in stages of another example method of formation. Referring to FIG. 4A, the microelectronic device 400 includes a photonic die 404 with at least one first photonic I/O port 406 for photonic signals. The photonic die 404 may be coupled to a package substrate 408 of the microelectronic device 400 by a die attach material 410.

A support structure 426 of the microelectronic device 400 may be formed before forming the photonic connection 402; the completed photonic connection 402 is shown in FIG. 4D. The support structure 426 may provide a desired shape and form factor for the subsequently-formed photonic connection 402. The support structure 426 may be formed by a first additive process 446, which provides a first additive material 448. For example, the first additive process 446 may be any of the additive processes described in reference to FIG. 3A through FIG. 3F. Examples of the first additive material 448 include epoxy, ceramic slurry, or a thermoplastic, such as polylactic acid (PLA) or acrylonitrile butadiene styrene (ABS). Also, for example, the support structure 426 may extend from the photonic die 404 to the package substrate 408. In one version of this example, a separate support structure 426 may be formed for each subsequently-formed photonic connection 402. In another version, the support structure 426 may be formed to support more than one subsequently-formed photonic connection 402.

Referring to FIG. 4B, a first portion of the subsequently-formed photonic connection 402 is formed, such as a first portion of a dielectric cladding 424 surrounding a subsequently-formed dielectric signal pathway 414 of the photonic connection 402. Formation of the dielectric signal pathway 414 is depicted in FIG. 4C. The first portion of the dielectric cladding 424 may be formed partly on the support structure 426. In this example, the first portion of the dielectric cladding 424 may be formed by a second additive process 450, which may include a photo-polymerization additive process, as depicted in FIG. 4B. An example photo-polymerization additive process may include a monomer source 452 provided to an extrusion head 454, which dispenses a second additive material 456 including the monomer onto the microelectronic device 400, and an ultraviolet (UV) light source 458, such as a UV laser or UV light emitting diode (LED), which polymerizes the dispensed monomer in the second additive material 456 as it is extruded from the extrusion head 454. The second additive material 456 may include photo-curable epoxy or such, and may also include organic polymer material, silicone organic polymer material, or nanoparticles of inorganic dielectric material, such as silicon dioxide or aluminum oxide, suitable for a material having an index of refraction lower than the subsequently-formed dielectric signal pathway 414. Other additive processes for the second additive process 450, including any of the additive processes described in reference to FIG. 3A through FIG. 3F, are within the scope of this example.

Referring to FIG. 4C, the dielectric signal pathway 414 is formed on the first portion of the dielectric cladding 424 using a third additive process 460, which may include a direct laser deposition process, as depicted in FIG. 4B. An example of a direct laser deposition process may use a scanned imaging and pulsed laser system 462 to eject discrete portions of a third additive material 464 from a ribbon 466; the ejected portions of the third additive material 464 form the first portion of the dielectric cladding 424. The third additive material 464 may include material having a higher index of refraction than the dielectric cladding 424, such as diamond nanoparticles, boron nitride nanoparticles, zirconium oxide nanoparticles, or hafnium oxide nanoparticles. Other additive processes may be used to form the dielectric signal pathway 414, including any of the additive processes described in reference to FIG. 3A through FIG. 3F.

Referring to FIG. 4D, a second portion of the dielectric cladding 424 is formed on the dielectric signal pathway 414. The second portion of the dielectric cladding 424 may be formed by a fourth additive process 468, which provides a fourth additive material 470. The fourth additive process 468 may be similar to the second additive process 450 of FIG. 4B used to form the first portion of the dielectric cladding 424. Alternatively, the fourth additive process 468 may be different from the second additive process 450, and it may include any of the additive processes described in reference to FIG. 3A through FIG. 3F.

Forming the photonic connection 402 using additive processes may accrue similar advantages to those described in reference to FIG. 3A through FIG. 3F. Other instances of photonic connections to the photonic die 404 may be formed in parallel with the photonic connection 402. Subsequently, formation of the microelectronic device 400 may proceed by forming additional package elements, such as assembly of a package base and package lid, or the like.

Various features of the examples described herein may be combined in other manifestations of example integrated circuits. For example, the additive processes described in reference to FIG. 3A through FIG. 3F may be used to form the structure of FIG. 2A and FIG. 2B. Similarly, the additive processes described in reference to FIG. 4A through FIG. 4D may be used to form the structure of FIG. 1A and FIG. 1B.

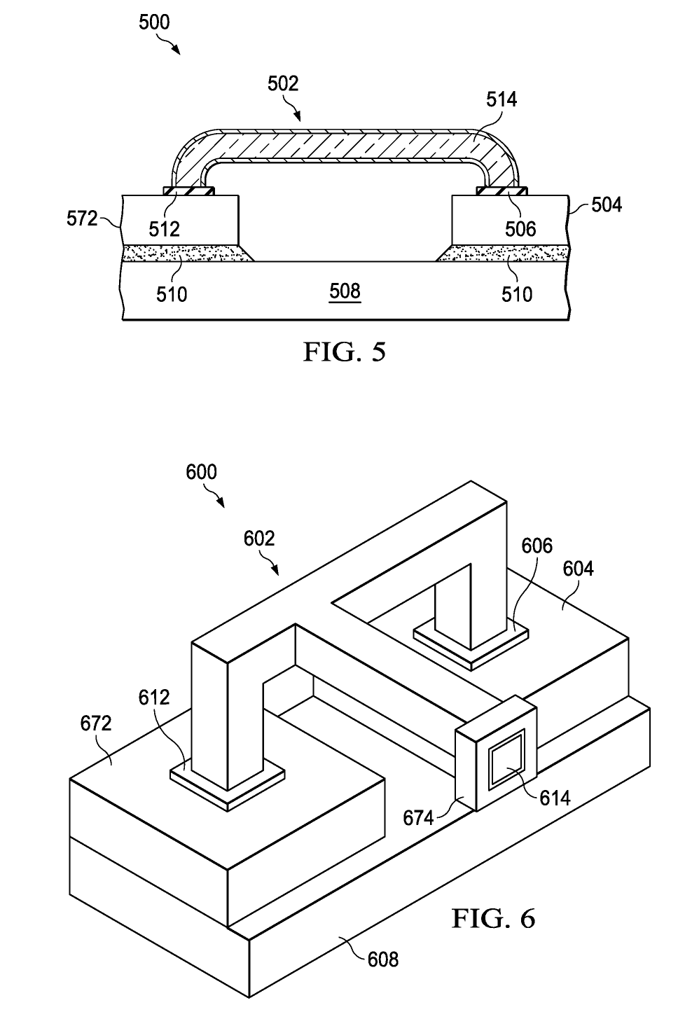

FIG. 5 is a cross section of a further example microelectronic device 500 having at least one photonic connection 502. In this example, the microelectronic device 500 includes a first photonic die 504 and a second photonic die 572. Both the first photonic die 504 and the second photonic die 572 are configured to process photonic signals. The first photonic die 504 includes a first photonic I/O port 506 to transmit or receive at least a portion of the photonic signals. Similarly, the second photonic die 572 includes a second photonic I/O port 512 to transmit or receive at least a portion of the photonic signals. In this example, the photonic connection 502 extends from the first photonic I/O port 506 to the second photonic I/O port 512. The photonic connection 502 includes a dielectric signal pathway 514, which provides a transmission path for the photonic signals. The photonic connection 502 may have the structure of any of the examples described herein, such as the example described in reference to FIG. 1A and FIG. 1B, or the example described in reference to FIG. 2A and FIG. 2B. Other architectures for the photonic connection 502 are within the scope of this example. At least a portion of the photonic connection 502 is formed by an additive process. The additive process or processes may include any of the examples described herein, such as binder jetting, material jetting, directed energy deposition, material extrusion, material jetting, powder bed fusion, sheet lamination, vat photopolymerization, direct laser deposition, electrostatic deposition, laser sintering, electrochemical deposition, and photo-polymerization extrusion.

FIG. 6 is a cross section of another example microelectronic device 600 having at least one photonic connection 602. In this example, the microelectronic device 600 includes a first photonic die 604 and a second photonic die 672. Both the first photonic die 604 and the second photonic die 672 are configured to process photonic signals. The first photonic die 604 includes a first photonic I/O port 606 to transmit or receive at least a portion of the photonic signals. Similarly, the second photonic die 672 includes a second photonic I/O port 612 to transmit or receive at least a portion of the photonic signals. In this example, the microelectronic device 600 includes a third photonic I/O port 674, which may be a photonic I/O port on another photonic die, also not shown, or may be a package photonic I/O port. The photonic connection 602 extends from the first photonic I/O port 606 to the second photonic I/O port 612. In this example, the photonic connection 602 extends to the third photonic I/O port 674. The photonic connection 602 may thus provide a mixer or splitter function for the microelectronic device 600. The photonic connection 602 includes a dielectric signal pathway 614, which provides a transmission path for the photonic signals. The photonic connection 602 may have the structure of any of the examples described herein. Other architectures for the photonic connection 602 of this example are within the scope of example embodiments. At least a portion of the photonic connection 602 is formed by an additive process.

Modifications are possible in the described embodiments, and other embodiments are possible, within the scope of the claims

1. A microelectronic device, comprising:
a first dielectric waveguide having a first end and a second end;
a die including a photonic port coupled to the first end; and
a structural package enclosing the die and the first dielectric waveguide, the structural package including a receptacle adapted to be connected to a second dielectric waveguide, and the receptacle being in alignment with the second end.

2. The microelectronic device of claim 1, wherein the first dielectric waveguide has a dielectric signal pathway and an electrically conductive envelope surrounding the dielectric signal pathway.

3. The microelectronic device of claim 2, wherein the electrically conductive envelope includes electrically conductive nanoparticles.

4. The microelectronic device of claim 1, wherein the first dielectric waveguide has a dielectric signal pathway and a dielectric cladding surrounding the dielectric signal pathway, the dielectric cladding having a lower index of refraction than the dielectric signal pathway.

5. The microelectronic device of claim 1, wherein the first dielectric waveguide includes at least one of an organic polymeric dielectric material, a silicone organic polymeric dielectric material, or an inorganic dielectric material.

6. The microelectronic device of claim 1, wherein the first dielectric waveguide is disposed on a support structure, the support structure extending to the photonic die.

7. The microelectronic device of claim 1, wherein the structural package includes an encapsulation material, and the first dielectric waveguide is surrounded and contacted by the encapsulation material.

8. The microelectronic device of claim 1, wherein the receptacle is a photonic receptacle that includes a lens in alignment with the second end.

9. (canceled)

10. The microelectronic device of claim 1, wherein: the photonic port is a first photonic port; the receptacle is a first receptacle; the microelectronic device includes a third dielectric waveguide having a third end and a fourth end; the die includes a second photonic port coupled to the third end; and the structural package includes a second receptacle adapted to be connected to a fourth dielectric waveguide, the second receptacle being in alignment with the fourth end.

11. A method of forming a microelectronic device, the method comprising:
forming a first dielectric waveguide having a first end and a second end, including by at least one additive process that, includes selectively placing material for the first dielectric waveguide in a region for the first dielectric waveguide;
on a die, forming a photonic port coupled to the first end; and
forming a structural package enclosing the die and the first dielectric waveguide, the structural package including a receptacle adapted to be connected to a second dielectric waveguide, and the receptacle being in alignment with the second end.

12. The method of claim 11, wherein the additive process includes at least one of binder jetting, material jetting, directed energy deposition, material extrusion, material jetting, powder bed fusion, sheet lamination, vat photopolymerization, direct laser deposition, electrostatic deposition, laser sintering, electrochemical deposition, or photo-polymerization extrusion.

13. The method of claim 11, wherein the additive process provides an additive material to the first dielectric waveguide, which includes a binder material.

14. The method of claim 11, wherein the additive process provides an additive material to the first dielectric waveguide, which includes a solvent.

15. The method of claim 11, wherein the additive process provides an additive material to the first dielectric waveguide, which includes nanoparticles.

16. The method of claim 11, wherein the additive process provides an additive material to the first dielectric waveguide, which includes at least one of an organic polymeric dielectric material, a silicone organic polymeric dielectric material, or an inorganic dielectric material.

17. The method of claim 11, wherein forming the first dielectric waveguide includes heating at least a portion of the first dielectric waveguide after performing the additive process.

18. The method of claim 11, further comprising forming a support structure, wherein forming the first dielectric waveguide includes forming the first dielectric waveguide on the support structure.

19. The method of claim 11, wherein forming the first dielectric waveguide includes forming a dielectric signal pathway and an electrically conductive envelope surrounding the dielectric signal pathway.

20. The method of claim 11, wherein forming the first dielectric waveguide includes forming a dielectric signal pathway and a dielectric cladding surrounding the dielectric signal pathway, the dielectric cladding having a lower index of refraction than the dielectric signal pathway.

21. The method of claim 11, wherein the receptacle is a photonic receptacle that includes a lens in alignment with the second end.
